(19) United States
(12) Patent Application Publication
(10) Pub. No.: US 2010/0101620 A1
(43) Pub. Date: Apr. 29, 2010

(54) Thermoelectric Conversion Module

(75) Inventor: Koichi Tanaka, Kagoshima (JP)

Correspondence Address: PROCOPIO, CORY, HARGREAVES & SAVITCH LLP, 530 B STREET, SUITE 2100, SAN DIEGO, CA, 92101, US

(73) Assignee: KYOCERA CORPORATION, Kyoto (JP)

(21) Appl. No.: 12/570,310

(22) Filed: Sep. 30, 2009

(30) Foreign Application Priority Data
Oct. 29, 2008 (JP) 2008-278118
Mar. 26, 2009 (JP) 2009-075756

(51) Int. Cl. H01L 35/30

(52) U.S. Cl. 136/205

(57) ABSTRACT

A thermoelectric conversion device with reduced thermal stress between a thermoelectric conversion element and a substrate is disclosed. Solders are between a first conductor and first end faces of a plurality of thermoelectric conversion elements and between a second conductor and second end faces of the thermoelectric conversion elements. At least one of the first conductor and the second conductor comprises at least one protrusion which protrudes toward one of the thermoelectric conversion elements. The at least one protrusion is in an area of at least one of the first end faces and second end faces, and coated by the solder.

### CROSS-REFERENCE TO RELATED APPLICATIONS

The present application claims priority under 35 U.S.C. §119 to Japanese Patent Application No. 2008-278118, filed, Oct. 29, 2008, and Japanese Patent Application No. 2009-075756, filed, Mar. 26, 2009, entitled “THERMOELECTRIC CONVERSION MODULE,” the content of which are incorporated by reference herein in their entirety.

### FIELD OF THE INVENTION

Embodiments of the present disclosure relate generally to thermoelectric devices, and more particularly relate to thermoelectric temperature control and power generation.

### BACKGROUND

A thermoelectric conversion element is a device which, when current is supplied in a p-n junction pair including a p-type semiconductor and an n-type semiconductor, one end of each of the semiconductors generates heat and the other end thereof absorbs heat. A thermoelectric conversion module equipped with modular thermoelectric conversion elements may be used in a wide range of devices such as, for example, cooling devices free from chlorofluorocarbons, cooling devices for photo detection elements, cooling devices for semiconductor manufacturing apparatuses, temperature adjusting devices for laser diodes, and the like. The thermoelectric conversion module generally comprises a substrate, a p-type thermoelectric conversion element and an n-type thermoelectric conversion element (hereinafter, sometimes referred to as a thermoelectric conversion element) located on the substrate, conductors located between the substrate and the thermoelectric conversion element, and solder which joins both end faces of the thermoelectric conversion element to the conductors, respectively.

To reduce peel-off of the conductors from the substrate or from the thermoelectric conversion element due to thermal stress, the substrate may have a circular or a polygon shape. Furthermore, to improve mechanical strength, the thermoelectric conversion element can be shaped such that a cross sectional area parallel to a bottom face and a top face thereof is continuously reduced from the bottom face to the top face.

Further, in some thermoelectric conversion modules, both end faces of their thermoelectric conversion elements may be located between a pair of substrates joined to the substrates respectively with a metal member. The metal member may be joined to the thermoelectric conversion element with brazing material or adhesive (solder). For example, the metal member can have a convex portion in contact with a part of the end face of the thermoelectric conversion element and brazing material or adhesive surrounding a side of the convex portion.

In thermoelectric conversion modules, thermal stress due to a rapid change in temperature can be generated between the thermoelectric conversion element and the solder, or between the conductors and the substrate. It can be generated also between the thermoelectric conversion element and the solder (element joining solder) or between the conductors and the substrate. The thermal stress can generate cracking or peel-off.

Accordingly, there is a need for thermoelectric conversion devices with reduced thermal stress between a thermoelectric conversion element and other components such as a substrate.

### SUMMARY

A thermoelectric conversion device with reduced thermal stress between a thermoelectric conversion element and a substrate is disclosed. Solders are located at least one of between a first conductor and first end faces of a plurality of thermoelectric conversion elements and between a second conductor and second end faces of the thermoelectric conversion elements. At least one of the first conductor and the second conductor comprises at least one protrusion which protrudes toward the thermoelectric conversion elements in an area of at least one of the first end faces and second end faces, and the solder coats the protrusion.

A first embodiment comprises a thermoelectric conversion module. The thermoelectric conversion module comprises a first substrate comprising a first principal surface, and a plurality of thermoelectric conversion elements on the first principal surface comprising first end faces and second end faces. The thermoelectric conversion module further comprises first conductors between the first principal surface and the first end faces operable to electrically connect the thermoelectric conversion elements to each other, and second conductors between the first principal surface and the second end faces operable to electrically couple the thermoelectric conversion elements to each other. The thermoelectric conversion module also comprises first solders at least one of between the first conductors and the first end faces and between the second conductors and the second end faces. At least one of the first conductors and the second conductors comprise at least one first protrusion which protrudes toward the thermoelectric conversion elements and is coated by one of the first solders.

A second embodiment comprises an optical transmission module. The optical transmission module comprises a package and a thermoelectric conversion module on the package and a second solder. The thermoelectric conversion module comprises a first substrate comprising a second principal surface, a first junction layer between the package and the second principle surface comprising a metal or an alloy, and at least one second protrusion in the first junction layer outwardly protruding. The optical transmission module also comprises a second solder located between the first junction layer and the package.

A third embodiment comprises a thermoelectric conversion module. The thermoelectric conversion module comprises a first substrate comprising a first principal surface and a second principal surface, and a plurality of thermoelectric conversion elements on the first principal surface of the first substrate comprising first end faces and second end faces. The thermoelectric conversion module further comprises first conductors between the first principal surface and the first end faces operable to electrically connect the thermoelectric conversion elements to each other, and second conductors on the second faces operable to electrically connect the second end faces to each other. The thermoelectric conversion module also comprises first solders at least one of between the first conductors and the first end faces and between the second conductors and the second end faces. The thermoelectric conversion module further comprises a first junction layer on the second principal surface, comprising a metal or an alloy. The first junction layer comprises at least one second protrusion extending away from the thermoelectric conversion elements.

### BRIEF DESCRIPTION OF THE DRAWINGS

Embodiments of the present disclosure are hereinafter described in conjunction with the following figures, wherein like numerals denote like elements. The figures are provided for illustration and depict exemplary embodiments of the disclosure. The figures are provided to facilitate understanding of the disclosure without limiting the breadth, scope, scale, or applicability of the disclosure. The drawings are not necessarily made to scale.

FIG. 1 is an illustration of a perspective view of an exemplary thermoelectric conversion module according to an embodiment of the disclosure, where a part of a substrate is pictorially omitted.

FIG. 2 is an illustration of an enlarged sectional view of FIG. 1 taken along section II-II.

FIG. 3 is an illustration of a sectional view taken along line III-III in FIG. 2.

FIG. 4 is an illustration of a schematic view of a protrusion.

FIG. 5 is an illustration of a sectional view taken along line V-V in FIG. 2.

FIG. 6 is an illustration of an elongated sectional view of an exemplary thermoelectric conversion module according to an embodiment of the disclosure.

FIG. 7 is an illustration of an elongated sectional view of an exemplary optical transmission module according to an embodiment of the disclosure.

FIG. 8 is an illustration of a plane view of the optical transmission module of FIG. 7 shown from a package side.

FIG. 9 is an illustration of a plane view of the optical transmission module of FIG. 7 shown from a heat sink side.

FIG. 10 is an illustration of an exemplary table showing experimental values according to an embodiment of the disclosure.

FIG. 11 is an illustration of an exemplary table showing experimental values according to an embodiment of the disclosure.

FIG. 12 is an illustration of an exemplary table showing experimental values according to an embodiment of the disclosure.

### DETAILED DESCRIPTION OF EXEMPLARY EMBODIMENTS

The following description is presented to enable a person of ordinary skill in the art to make and use the embodiments of the disclosure. The following detailed description is exemplary in nature and is not intended to limit the disclosure or the application and uses of the embodiments of the disclosure. Descriptions of specific devices, techniques, and applications are provided only as examples. Modifications to the examples described herein will be readily apparent to those of ordinary skill in the art, and the general principles defined herein may be applied to other examples and applications without departing from the spirit and scope of the disclosure. Furthermore, there is no intention to be bound by any expressed or implied theory presented in the preceding technical field, background, brief summary or the following detailed description. The present disclosure should be accorded scope consistent with the claims, and not limited to the examples described and shown herein.

Embodiments of the disclosure are described herein in the context of one practical non-limiting application, namely, a thermoelectric conversion module. Embodiments of the disclosure, however, are not limited to such thermoelectric conversion module applications, and the techniques described herein may also be utilized in other applications. For example, embodiments may be applicable to cooling devices, power generating devices, temperature adjusting devices, and the like.

As would be apparent to one of ordinary skill in the art after reading this description, these are merely examples and the embodiments of the disclosure are not limited to operating in accordance with these examples. Other embodiments may be utilized and structural changes may be made without departing from the scope of the exemplary embodiments of the present disclosure.

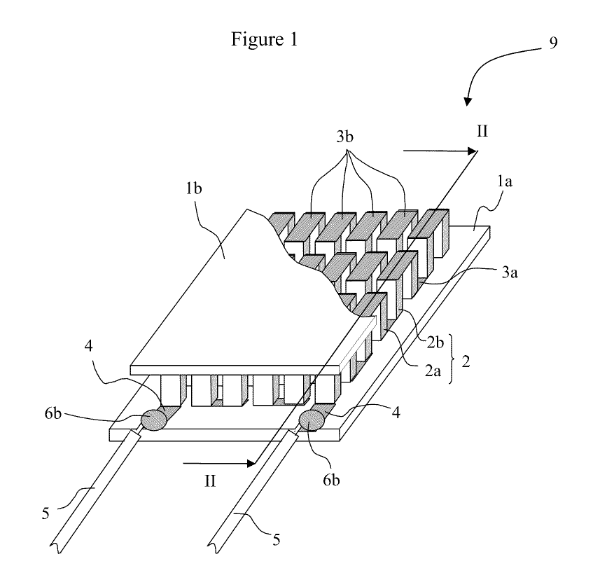

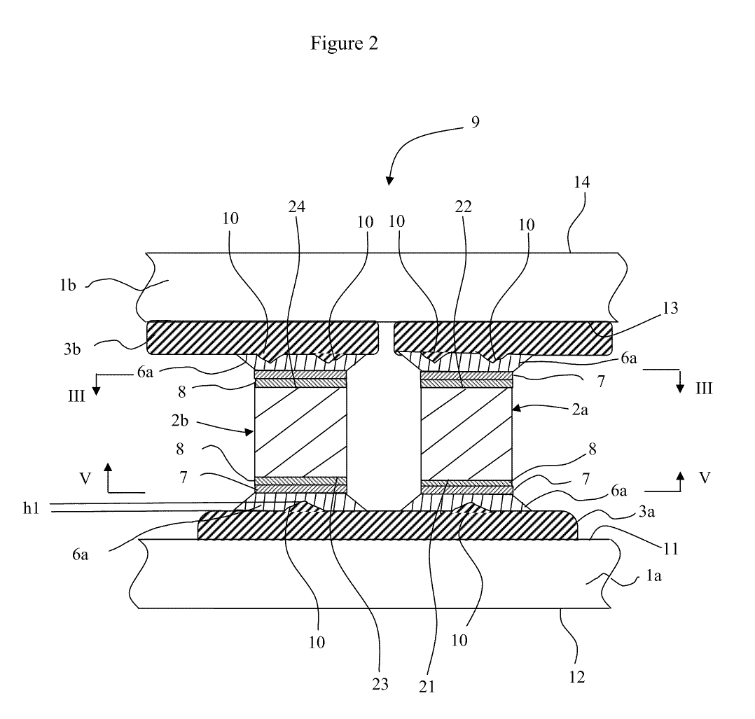

FIGS. 1 and 2 are illustrations of an exemplary thermoelectric conversion module 9 according to an embodiment of the disclosure. The thermoelectric conversion module 9 comprises: a first and a second substrates 1a and 1b, a p-type thermoelectric conversion element 2a, and an n-type thermoelectric conversion element 2b (hereinafter, may be called thermoelectric conversion element 2, or the thermoelectric conversion elements 2a and 2b), first and second conductors 3a and 3b (hereinafter, may be called conductor 3), and a first solder 6a (element joining solder 6a in FIG. 2).

The first substrate 1a comprises a first principal surface 11 and a second principal surface 12. The second substrate 1b comprises a first principal surface 13 and a second principal surface 14. The first substrate 1a is opposed to the second substrate 1b. Specifically, the first principal surface 11 of the first substrate 1a is opposed to the first principal surface 13 of the second substrate 1b. In the embodiment shown in FIGS. 1 and 2, the first substrate 1a is located at a bottom portion of the thermoelectric conversion module 9, and the second substrate 1b is located at a top portion thereof. That is, the first substrate 1a is located below the second substrate 1b.

The first and second conductors 3a and 3b are located on the first principle surfaces of the first substrate 1a and the second substrate 1b opposed to each other, respectively. More specifically, the first conductor 3a is located on the first principal surface 11 of the first substrate 1a, and the second conductor 3b is located on the first principal surface 13 of the second substrate 1b.

Further, the thermoelectric conversion elements 2a and 2b are arranged between the first substrate 1a and the second substrate 1b. The thermoelectric conversion elements 2a and 2b comprise first end faces 21 and 23 located at the bottom portion, and second end faces 22 and 24 located at the top portion, respectively. Both end faces 21/22 of the thermoelectric conversion element 2a are joined to the first and second conductors 3a and 3b, located at the bottom and the top portions, respectively, with the first solder 6a (element joining solder 6a). Both end faces 23/24 of the thermoelectric conversion element 2b are also joined to the first and second conductors 3a and 3b, respectively, with the first solder 6a.

The first conductor 3a is located between the first principal surface 11 of the first substrate 1a and the first end face 21 of the thermoelectric conversion element 2a and between the first principal surface 11 of the first substrate 1a and the first end face 23 of the thermoelectric conversion element 2b. The first conductor 3a electrically connects the thermoelectric conversion elements 2a and 2b to each other. The second conductor 3b is located between the first principal surface 13 of the second substrate 1b and the second end face 22 of the thermoelectric conversion element 2a and between the first principal surface 13 of the second substrate 1b and the second end face 24 of the thermoelectric conversion element 2b. The second conductor 3b electrically connects the second end faces 22 and 24 of the thermoelectric conversion elements 2a and 2b to second end faces of another adjacent thermoelectric conversion elements, respectively.

Further, the first solder 6a is located between the first conductor 3a and the first end face 21 of the thermoelectric conversion element 2a and between the first conductor 3a and the first end face 23 of the thermoelectric conversion element 2b, as well as between the second conductor 3b and the second end face 22 of the thermoelectric conversion element 2a and between the second conductor 3b and the second end face 24 of the thermoelectric conversion element 2b. That is, the solder 6a joins the conductors 3a and 3b to the thermoelectric conversion element 2.

In the embodiment shown in FIGS. 1 and 2, the respective thermoelectric conversion elements 2a and 2b are individually joined to the conductors 3a and 3b by their respective first solders 6a. In this manner, two first solders 6a are located on the conductors 3a. Alternatively, a pair of thermoelectric conversion elements 2a and 2b may be joined by one first solder 6a. In this manner, one first solder may be made by connecting two first solders 6a located on the conductors 3a.

Furthermore, in the embodiment shown in FIGS. 1 and 2, the thermoelectric conversion elements 2a and 2b are located between the first and second substrates 1a and 1b. Alternatively, the second substrate 1b located at the top portion may not be provided. That is, the second end faces 22 and 24 of the thermoelectric conversion elements 2a and 2b may be electrically coupled to the second conductor 3b.

The thermoelectric conversion element 2 has two types of the p-type thermoelectric conversion element 2a and the n-type thermoelectric conversion element 2b, which are arranged in a matrix on the first principal surface 11 of the first substrate 1a located at the bottom portion.

The p-type thermoelectric conversion elements 2a and the n-type thermoelectric conversion elements 2b are connected by the first and second conductors 3a and 3b (hereinafter, sometimes referred to as the conductors 3a and 3b) so as to be alternately located in p-type, n-type, p-type, and n-type, and so on, as well as to be in series. The p-type thermoelectric conversion elements 2a and the n-type thermoelectric conversion elements 2b are thus connected to form one electric circuit.

The thermoelectric conversion element 2 may be made of, for example but without limitation, Bi—Te materials having excellent thermoelectric conversion performance near a normal temperature. This makes it possible to obtain a good cooling effect. For example, Bi_{0.4}Sb_{1.6}Te₃, Bi_{0.5}Sb_{1.5}Te₃, or the like may be used as the p-type; and Bi₂Te_{2.85}Se_{0.15}, Bi₂Te_{2.9}Se_{0.1}, or the like may be used as the n-type.

An electrode 8 made of Ni or the like and a coating layer 7 made of Au or the like, both of which having good wettability with the first solder 6a, are located between the thermoelectric conversion element 2a and the conductors 3a and 3b and between the thermoelectric conversion element 2b and the conductors 3a and 3b.

As shown in FIG. 1, both ends of the single electric circuit are electrically connected to external connection terminals 4, respectively. The external connection terminals 4 are coupled to lead wires 5 by a fourth solder 6b (lead wire joining solder 6b). This arrangement allows electric power to be supplied from outside the thermoelectric conversion module 9 to the thermoelectric conversion elements 2a and 2b. The external connection terminal 4 may be connected to a block shaped or columnar shaped conductor in place of the lead wire 5. Alternatively, the external connection terminal 4 may be directly bonded to a wire without being connected to the lead wire 5 or the block shaped or columnar shaped conductor. This arrangement also makes it possible to supply electric power from the outside to the electric circuit.

As shown in FIG. 2, the first and second conductors 3a and 3b each comprise one or more first protrusions 10. The first protrusions 10 protrude toward the thermoelectric conversion element 2. Some of the first protrusions 10 are located on a top face of the first conductor 3a and are protruded toward the thermoelectric conversion elements 2a and 2b. The remaining first protrusions 10 are located on a bottom face of the second conductor 3b and are protruded toward the thermoelectric conversion elements 2a and 2b. That is, the first protrusions 10 inwardly protrude.

Using such first protrusions 10, thermal stress between the thermoelectric conversion element 2a and the substrates 1a and 1b and between the thermoelectric conversion element 2b and the substrates 1a and 1b can be reduced. Therefore, a crack or peel-off between the thermoelectric conversion element 2a and the substrates 1a and 1b as well as between the thermoelectric conversion element 2b and the substrates 1a and 1b can be reduced. As a result, breakage of the thermoelectric conversion module due to a repeated temperature cycle can be reduced.

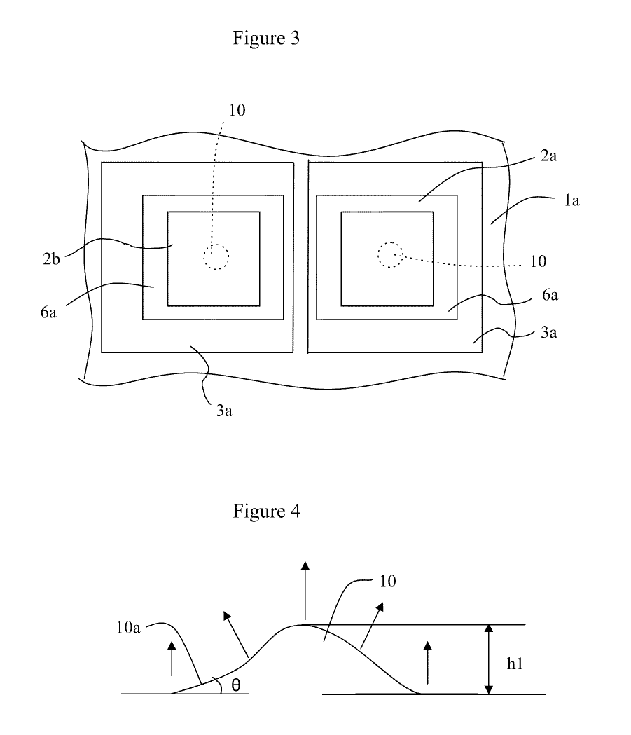

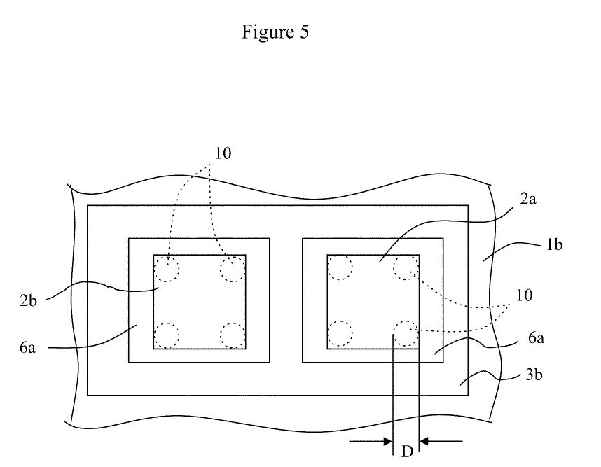

Shapes of the first protrusions 10 may be, for example but without limitation, substantially circular or substantially rectangular when seen from an inner side (a side closed to the thermoelectric element 2). For example, in the embodiment shown in FIGS. 3 and 5, the shape of the first protrusion 10 is substantially circular as shown from the inner side.

Besides, the first protrusions 10 are located in areas of the surfaces of the first and second conductors 3a and 3b, the areas being opposed to the end faces 21 to 24 of the thermoelectric conversion elements 2a and 2b, respectively. The first protrusions 10 are coated by the first solder 6a. In other words, the first solder 6a is located between the first protrusions 10 and the thermoelectric conversion element 2a and between the first protrusions 10 and the thermoelectric conversion element 2b. In this manner, the first protrusions 10 do not come into direct contact with the thermoelectric conversion elements 2a and 2b.

Supposing that upper ends of the thermoelectric conversion elements 2a and 2b are the sides to absorb heat; and lower ends thereof are the sides to radiate heat. That is, the upper ends of the thermoelectric conversion elements 2a and 2b are portions having a low temperature; and lower ends of the thermoelectric conversion elements 2a and 2b are portions having a high temperature.

In this case, at the upper ends of the thermoelectric conversion elements 2a and 2b having a low temperature, heat is conducted from the substrate 1b to the thermoelectric conversion elements 2a and 2b via the first conductor 3b and the first solders 6a. Concurrently, outer peripheral portions of the end faces 22 and 24 of the thermoelectric conversion elements 2a and 2b are exposed to the air and have a higher temperature than central portions.

On the other hand, at the lower ends of the thermoelectric conversion elements 2a and 2b having a high temperature, heat is conducted from the lower ends of the thermoelectric conversion elements 2a and 2b to the substrate 1a. Concurrently, the temperature at central portions of the end faces 21 and 23 of the thermoelectric conversion elements 2a and 2b is higher than the temperature of outer peripheral portions of the end faces 21 and 23, because the outer peripheral portions are exposed to the air.

In the present embodiment, at the upper ends of the thermoelectric conversion elements 2a and 2b having a low temperature, as shown in FIG. 3, the first protrusions 10 are located in areas opposed to the outer peripheral portions of the end faces 22 and 24 of the thermoelectric conversion elements 2a and 2b. In this manner, it is possible to scatter heat, which is transferred from the substrate 1b, into various directions by the first protrusions 10 as shown in FIG. 4. Therefore, heat to be transferred to the outer peripheral portions of the end faces 22 and 24 having a higher temperature than the central portions of the end faces 22 and 24 is effectively scattered by the first protrusions 10. As a result, the temperature difference is reduced between the end face 22 of the thermoelectric conversion elements 2a and the adjacent first solder 6a and between the end face 24 of the thermoelectric conversion elements 2b and the adjacent first solder 6a. Therefore, thermal stress between the first solder 6a and the thermoelectric conversion element 2a and between the first solder 6a and the thermoelectric conversion element 2b can be more effectively decreased.

As shown in FIG. 5, on the lower ends of the thermoelectric conversion elements 2a and 2b having a high temperature, one first protrusion 10 is located in an area opposed to each central portion of the end faces 21 and 23 of the thermoelectric conversion elements 2a and 2b. In this manner, heat which is transferred from the thermoelectric conversion elements 2a and 2b to the substrate 1a is scattered into various directions by the first protrusions 10. Therefore, heat, which is transferred from the central portions of the end faces 21 and 23 having a higher temperature than the outer peripheral portions of the end faces 21 and 23, is effectively scattered by the first protrusions 10. As a result, the temperature difference between the substrate 1a and each of the conductors 3a is reduced. Therefore, thermal stress between the substrate 1a and each of the conductors 3a can be effectively decreased.

Consequently, thermal stress due to rapid change in temperature is reduced between the thermoelectric conversion element 2a and the first solder 6a, between the thermoelectric conversion element 2b and the first solder 6a, and between the substrate 1a and each of the conductors 3a. As a result, a likelihood of a crack or peel-off is reduced between the thermoelectric conversion element 2a and the first solder 6a, between the thermoelectric conversion element 2b and the first solder 6a, and between the substrate 1a and each of the conductors 3a. Such a thermoelectric conversion module can be stably used for a long period of time.

In the embodiment shown in FIG. 4, the first protrusion 10 of the conductor 3 comprises a foot 10. The foot 10a is located at a portion close to the substrate 1 (i.e., substrate 1 comprising substrate 1a and 1b) and is sprawled. More specifically, in a cross section of the first protrusion 10 substantially perpendicular to the surface of the substrate 1, the dimension of the first protrusion 10 in a direction along the surface of the substrate 1 is larger at a side of the protrusion 10 close to the substrate 1 than at a side of the protrusion 10 close to the thermoelectric conversion element 2. This reduces stress to be concentrated at the side of the protrusion 10 close to the substrate 1. An angle θ of the foot 10a may be not more than 70 degrees. The angle θ may be not more than 70 degrees and accordingly stress concentrated at the side of the protrusion 10 close to the substrate 1 is reduced, and concentration of thermal stress is effectively reduced. The angle θ of the foot 10a may be at most about 50-60 degrees. The angle θ may be an angle between a surface of the conductor 3 and a surface of the foot 10a shown in FIG. 4, measured by scanning the protrusion 10 and calculating with a three dimension measuring instrument.

Furthermore, as shown in FIG. 2, the conductors 3b located above the thermoelectric conversion elements 2a and 2b comprise, for example but without limitation, four first protrusions 10 which are opposed to each of the outer peripheral portions of the end faces 22 and 24 of the thermoelectric conversion elements 2a and 2b. As shown in FIG. 5, the conductor 3a located below the thermoelectric conversion elements 2a and 2b each comprise one first protrusion 10 which is opposed to each central portion of the end faces 21 and 23 of the thermoelectric conversion elements 2a and 2b. Alternatively, the conductor 3b may comprise one first protrusion 10, and the conductor 3a may comprise a plurality of first protrusions 10. The first protrusion 10 may be solid, which reduces electric resistance of the conductor 3.

In the embodiments shown in FIGS. 2 and 5, four first protrusions 10 are located in an area opposed to each of the outer peripheral portions of the end faces 22 and 24 at the upper ends of the thermoelectric conversion elements 2a and 2b having a low temperature as shown in FIG. 5. As shown in FIGS. 2 and 3, one first protrusion 10 is located in an area opposed to each central portion of the end faces 21 and 23 at the lower ends of the thermoelectric conversion elements 2a and 2b having a high temperature. The positions of the first protrusions 10 are not limited to the above embodiments and may be varied to suitably scatter heat. For example, at the upper ends of the thermoelectric conversion elements 2a and 2b, four first protrusions 10 may be located in the area opposed to each of the outer peripheral portions of the end faces 22 and 24, while one first protrusion 10 may be located in an area opposed to each central portion of the end faces 22 and 24. On the contrary, at the lower ends of the thermoelectric conversion elements 2a and 2b, one first protrusion 10 may be located in an area opposed to each central portion of the end faces 21 and 23, while a plurality of first protrusions 10 may be located in an area opposed to each of the outer peripheral portions of the end faces 21 and 23.

Further, the first protrusion 10 may be located in an area of each of the conductors 3a and 3b that are not opposed to the end faces 21, 22, 23, or 24 of the thermoelectric conversion elements 2a and 2b. The first solder 6a is also located between each of the first protrusions 10 thus arranged and each of the end faces 21, 22, 23, and 24 of the thermoelectric conversion elements 2a and 2b. The first solder 6a covers the first protrusions 10, that is, the first protrusions 10 have no contact with the faces 21, 22, 23 and 24. Consequently, the first protrusions 10 thus arranged can scatter heat of inside the first solder 6a or inside the conductors 3a and 3b.

Moreover, if the shape of the first protrusion 10 is a circle when seen from the inner side, a maximum diameter D of the circle of the first protrusion 10 may be, without limitation, at least 3 μm to effectively increase heat scattering effects. Alternatively, the maximum diameter of the first protrusion 10 may be, without limitation, at least 5 μm or 8 μm. A height h1 of the first protrusion 10 may be, without limitation, at least 1 μm or at least 5 μm to effectively increase heat scattering effects.

The maximum diameter of the circle of the first protrusion 10 is a substantially maximum diameter of the first protrusion 10 of which shape is scanned and calculated using a laser displacement gauge. The height h1 of the first protrusion 10 is a height of the first protrusions 10 of which shape is scanned and calculated using the laser displacement gauge.

Furthermore, the number of the conductors 3a and 3b comprising the first protrusions 10 may be, without limitation, at least about 20% of the conductors 3a and 3b. The proportion of the conductors 3a and 3b comprising the first protrusions 10 is at least about 20% of the total number of the conductors 3a and 3b; and accordingly, heat scattering effect increases. The proportion of the conductors 3a and 3b comprising the first protrusions 10 may be, for example but without limitation, at least about 30% of the total number of the conductors 3a and 3b. In some embodiments, all the conductors 3a and 3b may comprise the first protrusions 10. The first protrusion 10 may be made, for example and without limitation, of the same material as the conductors 3a and 3b.

The conductors 3a and 3b supply electric power to the thermoelectric conversion element 2. For example, each of the conductors 3a and 3b may be made of a metal comprising, for example but without limitation, at least one type of element selected from Zn, Al, Au, Ag, W, Ti, Fe, Cu, Ni, Pt, and Pd, and the like. This makes it possible not only to reduce heat generation because the conductors 3a and 3b have low electric resistance but also to have excellent heat dissipation performance because the conductors 3a and 3b have high thermal conductivity. At least one type of element selected, for example but without limitation, from Cu, Ag, Al, Ni, Pt, and Pd, and the like may be used for the conductors 3a and 3b to provide suitable electric resistance, thermal conductivity, and cost.

The conductors 3a and 3b may be manufactured by, for example but without limitation, a plating method, a metallization method, a direct-bonding copper (DBC) method, a chip bonding method, a thick film method, and the like. The conductor 3 is manufactured by these manufacturing methods in accordance with accuracy of wiring patterns, current value, and cost. These manufacturing methods of the conductors 3a and 3b have respective features and are appropriately selected depending on purpose of use. For example, when a thickness of the conductors 3a and 3b is not more than 100 μm, the plating method and the metallization method may be used; and when the thickness is not less than 100 μm, the DBC method and the chip bonding method may be used.

A manufacturing method of the thermoelectric conversion module 9 according to one embodiment of the present disclosure is described below.

First, the thermoelectric conversion element 2 is prepared. For example, the thermoelectric conversion element 2 may be obtained by, for example but without limitation, a sintering method, a single crystal method, a melting method, a hot extrusion method, a thin film method, and the like.

The thermoelectric conversion element 2 may comprise a sintered body comprising at least one of Bi and Sb and at least one of Te and Se. These metals and alloys thereof enable to provide a thermoelectric conversion module with high performance near a room temperature. A size of the thermoelectric conversion element 2 is not particularly limited. For example, in a small embodiment of the thermoelectric conversion module 9, the thermoelectric conversion element 2 is processed into a prismatic shape of about 0.1 mm to about 2 mm in length, about 0.1 mm to about 2 mm in width, and about 0.1 mm to about 3 mm in height is usable.

The thermoelectric conversion element 2 may comprise the electrode 8 of Ni or the like and the coating layer 7 of Au or the like on the end faces to be joined with the first solder 6a in order to improve wettability with the first solder 6a.

Next, the substrate 1a and the substrate 1b (substrate 1) are prepared using, for example but without limitation, ceramics comprising alumina, aluminum nitride, silicon nitride, and silicon carbide, and the like, as a main component. Alternatively an insulating organic substrate is usable as the substrate 1. The substrate 1 is processed into a predetermined substrate shape, and then, the conductor 3 and the external connection terminal 4 are formed on the surface thereof using at least one type of the conductive material selected from, for example and without limitation, Zn, Al, Au, Ag, W, Ti, Fe, Cu, Ni, Pt, Pd, and the like. In this case, methods such as but without limitation, a plating method, a metallization method, a direct-bonding copper (DBC) method, a baking method, a chip bonding method, and the like can be used.

In the metallization method, the conductors 3 can be obtained by printing and baking a paste made of, for example and without limitation, Mn—Mo or W on a substrate made of ceramics or on a green sheet made of ceramics. In the DBC method, a metal plate of the conductor 3 is joined on the substrate 1 made of ceramics using an activated metal oxide, for example and without limitation, Ti, Zr, or Cr, and the like. In the chip bonding method, a metal plate of the conductor 3 is joined by solder or the like on a foundation formed on the substrate 1 made of ceramics by the plating method or the metallization method.

In the case of the plating method, the conductor 3 provided with the first protrusion 10 can be obtained by plating the substrate 1 previously attached with fine metal particles (seed crystal). Alternatively, the conductor 3 can also be obtained by using plating liquid in which fine metal particles are suspended. In this case, the metal particles are attached to the substrate 1 and the conductor 3 is grown on the basis of the metal particles; and accordingly, it is possible to obtain the conductor 3 provided with the first protrusion 10 on its surface.

In the metallization method and the baking method, a paste in which the metal particles serving as the protrusion are scattered is applied to the substrate 1 and baked. Accordingly, the conductor 3 comprising the first protrusion 10 can be obtained. The shape and dimension of the first protrusion 10, and the proportion of the conductors 3 comprising the first protrusions 10 can be controlled by the size, shape, and content rate of the metal particles.

In the DBC method and the chip bonding method, the conductor 3 in which the first protrusion 10 is formed by a machining or etching method is joined to the substrate 1. The shape and dimension of the first protrusion 10, and the proportion of the conductors 3 comprising the first protrusion 10 can be controlled by masking during machining or etching.

The angle θ of the foot 10a can be controlled by the shape of the metal particles to be attached to the substrate 1. Furthermore, the angle θ of the foot 10a can also be controlled by controlling a plating time. The shape and dimension of the first protrusion 10 can also be controlled by the shape, dimension, plating time, and the like of the metal particles to be attached to the substrate 1. The angle θ of the foot 10a can be measured using images obtained by scanning the shapes of the first protrusions 10 using the laser displacement gauge.

The conductor 3 may comprise a metal layer made of, for example and without limitation, Ni, Au, or the like on the end faces located at a side close to the thermoelectric conversion element 2 in order to improve wettability with the first solder 6a. In this case, the first protrusion 10 comprises, for example and without limitation, the metal layer made of Ni, Au, or the like on the end faces located at a side close to the thermoelectric conversion element 2.

Next, a solder paste is applied onto the conductor 3, and the thermoelectric conversion element 2 is arranged thereon and heated. This makes the thermoelectric conversion element 2 joined to the conductor 3 with the first solder 6a. The thermoelectric conversion element 2 is arranged such that the p-type thermoelectric conversion elements 2a and the n-type thermoelectric conversion elements 2b are alternately disposed and are electrically coupled in series. Accordingly, the thermoelectric conversion module 9 can be manufactured.

The lead wire 5 having 0.3 mm in diameter or the like is locally heated by soft beams to be joined to the external connection terminal 4.

Alternatively, the lead wire 5 may be jointed to the external connection terminal 4 by spot-welding using a YAG laser or the like. Further, in order to be adapted to wire bonding, a block shaped or columnar shaped conductor may be joined to the external connection terminal 4 in place of the lead wire 5. Wire-bonding can be directly applied to the external connection terminal 4.

The thermoelectric conversion module 9 according to an embodiment of the present disclosure can be used as a cooling unit for a semiconductor manufacturing apparatus or a laser apparatus. This makes it possible to provide a cooling device having excellent stability in long term.

Alternatively, the thermoelectric conversion module 9 may be configured as a power generating device, so as to be used as a power generating unit using exhaust heat from vehicles or cogeneration. This makes it possible to provide a power generating device having excellent stability in long term.

Further, the thermoelectric conversion module 9 can be used as a temperature adjusting unit for a laser diode. This makes it possible to provide a temperature adjusting device having excellent stability in long term.

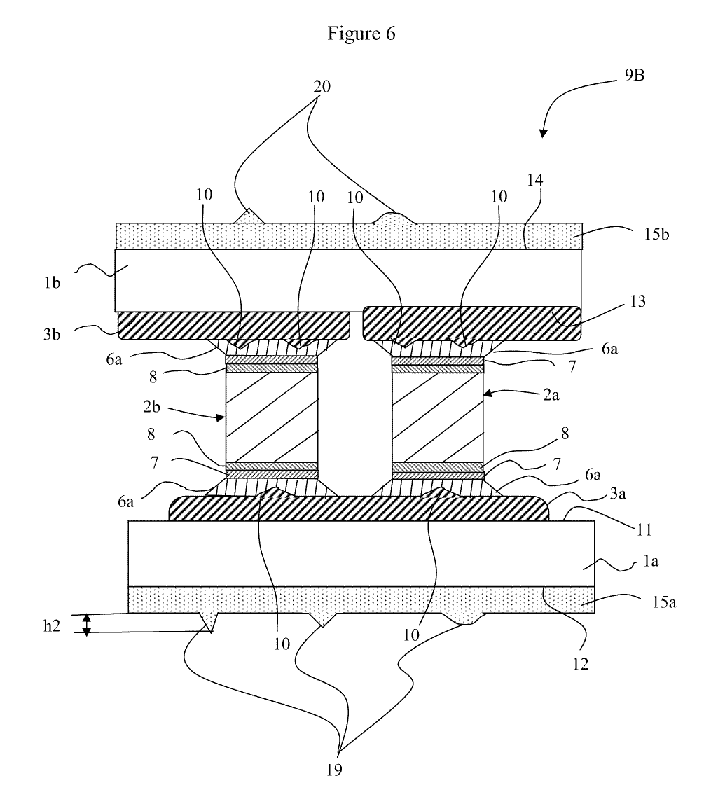

FIG. 6 shows a thermoelectric conversion module 9B according to another embodiment of the present disclosure. In this embodiment, a conductor 3 comprises a first protrusion 10 as shown in FIGS. 1, to 5. The thermoelectric conversion module 9B has a structure that is similar to a thermoelectric conversion module 9, common features, functions, and elements will not be redundantly described herein.

The thermoelectric conversion module 9B comprises a first junction layer 15a on a second principal surface 12 of a first substrate 1a and a second junction layer 15b on a second principal surface 14 of a second substrate 1b, respectively.

The first junction layer 15a comprises a second protrusion 19 which protrudes away from a thermoelectric conversion element 2. The second junction layer 15b comprises a third protrusion 20 which protrudes away from the thermoelectric conversion element 2. That is, the first and second junction layers 15a and 15b each comprise the second protrusion 19 and the third protrusion 20, both of which outwardly protrude.

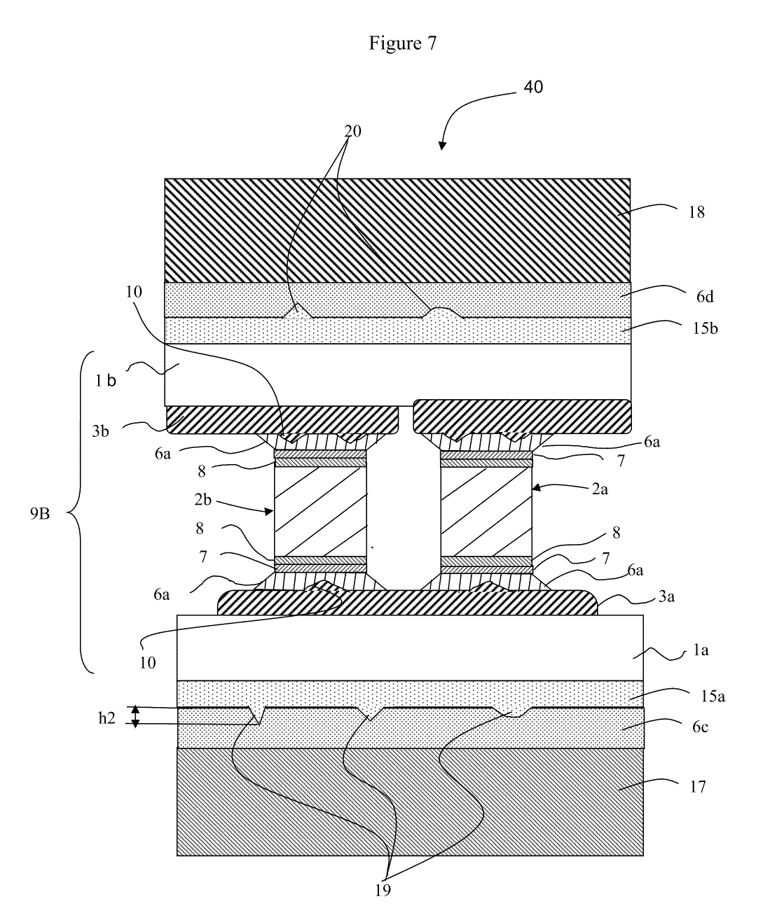

FIG. 7 shows a part of an optical transmission module 40 according to one embodiment of the present disclosure. The optical transmission module 40 comprises the thermoelectric conversion module 9B. The first junction layer 15a of the thermoelectric conversion module 9B is joined to a package 17 by a second solder 6c (module joining solder 6c), and a heat sink 18 equipped with a laser device (not shown) is joined to the second junction layer 15b of the thermoelectric conversion module 9B by a third solder 6d (heat sink joining solder 6d).

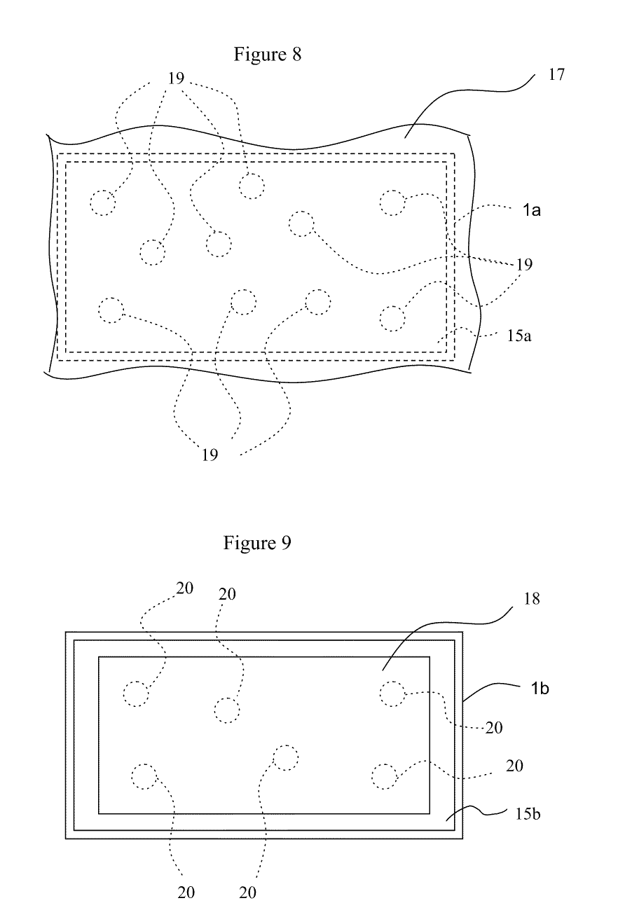

Specifically, the second protrusion 19 protrudes toward the package 17 on a bottom face of the first junction layer 15a; and the third protrusion 20 protrudes toward the heat sink 18 on a top face of the second junction layer 15b. The second protrusion 19 and the third protrusion 20 each have a protruding shape whose shapes when seen from the inner side are substantially circular or substantially rectangular. For example, in the embodiments shown in FIGS. 8 and 9, a shape of the second and third protrusions 19 and 20 is circular when seen from the inner side.

Upper ends of thermoelectric conversion elements 2a and 2b are made to absorb heat, and lower ends thereof are made to radiate heat. The second protrusion 19 is coated by the second solder 6c (module joining solder 6c) which joins the first junction layer 15a and the package 17. The third protrusion 20 is coated by the third solder 6d (heat sink joining solder 6d) which joins the second junction layer 15b and the heat sink 18. In other words, the second solder 6c is between the second protrusion 19 and the package 17 and the third solder 6d is between the third protrusion 20 and the heat sink 18, respectively.

In the optical transmission module 40 of the present embodiment, the first and second junction layers 15a and 15b comprise the second and third protrusions 19 and 20, respectively. This makes the second and third protrusions 19 and 20 dig into the second solder 6c and the third solder 6d, respectively. Therefore, even when the surfaces of the second solder 6c and the third solder 6d are softened, the second and third protrusions 19 and 20 function as spikes; and therefore, skid of the thermoelectric conversion module 9B and the heat sink 18 can be reduced. Materials for the first solder 6a, the fourth solder 6b, the second solder 6c, and the third solder 6d are not particularly limited as long as the materials have a sufficient temperature difference in melting point. For example, the solders 6c and 6d may be made of, for example but without limitation, Sn—Ag—Cu or Sn—Bi and the like. The solders 6a and 6b may be made of, for example but without limitation, Au—Sn or Sn—Sb, and the like. Melting points of the first and second junction layers 15a and 15b are higher than those of the solders 6a, 6b, 6c, and 6d.

The number of the second protrusions 19 in the first junction layer 15a having a high temperature is larger than that of the third protrusion 20 in the second junction layer 15b having a low temperature. That is, an area percentage of the second protrusions 19 in the surface of the first junction layer 15a is larger than an area percentage of the third protrusions 20 in the surface of the second junction layer 15b. This makes it possible to preferably reduce deviation of the thermoelectric conversion module 9B at the first junction layer 15a where solder is easy to be softened, and to reduce cost by decreasing the unnecessary third protrusions 20 in the second junction layer 15b.

In embodiments in shown FIGS. 8 and 9, the first junction layer 15a comprises ten second protrusions 19 at positions opposed to the package 17, and the second junction layer 15b comprises, for example but without limitation, six third protrusions 20 at positions opposed to the heat sink 18. More particularly, in the case where the first and second junction layers 15a and 15b comprise the second and third protrusions 19 and 20, respectively, which are located to be scatter at four corners or central portions thereof, positional deviation of the above element can be effectively reduced.

The second and third protrusions 19 and 20 may be solid. In this manner, heat transmission loss can be reduced, thereby improving performance as the thermoelectric conversion module.

Further, in the present embodiment, an area occupied by the second or third protrusions 19 or 20 in the surface of the first or second junction layer 15a or 15b (area percentage) may be at most about 50% of a total area of the first or second junction layers 15a and 15b respectively. If the area percentage occupied by the second or third protrusions 19 or 20 is not more than 50%, gas present in the solder 6c or 6d may be dissipated more easily upon joining. Therefore, occurrence of void in the solder 6c or 6d can be decreased. The area percentage occupied by the second or third protrusions 19 or 20 in the surface of the first or second junction layer 15a or 15b may be at most between about 25% to about 33%.

The area percentages of the second and third protrusions 19 and 20 can be calculated using photographs in which each of the first and second junction layers 15a and 15b is photographed from the inner side (photograph obtained when each of the first and second junction layers 15a and 15b is seen from the inner side). More specifically, the areas of the second and third protrusions 19 and 20 are calculated from the photographs using an image processing apparatus. Then, area ratios of the obtained areas in the whole surfaces of the first and second junction layers 15a and 15b in the photographs correspond to the area percentage.

Still further, a height h2 of the second and third protrusion 19 and 20 may be not less than 3 μm. The height h2 may be at least 3 μm. Accordingly, an effect of the function as the spikes against the positional deviation increases. The height h2 of the second and third protrusions 19 and 20 may also be at least 5 μm or at least 8 μm. The height h2 of the second and third protrusions 19 and 20 can be obtained by measurement using a three coordinate measuring instrument. A height of each of the second and third protrusions 19 and 20 can be measured by obtaining a height protruding from the reference face which is a portion sufficiently apart from the target protrusion on the surface of the junction layer 15a or 15b.

The junction layers 15a and 15b may be made of a metal comprising, for example but without limitation, at least one element selected from Zn, Al, Au, Ag, W, Ti, Fe, Cu, Ni, Pt, and Pd, and the like. There is an advantage in cost when the junction layers 15a and 15b and the conductors 3a and 3b are manufactured in the same process; therefore, as the materials for the junction layer 15a and 15b, elements similar to those of the conductors 3a and 3b may be used.

The junction layers 15a and 15b may be manufactured by the same method as the manufacturing method of the conductors 3a and 3b.

For example, in the case of the plating method, the junction layers 15a and 15b comprising the second and third protrusions 19 and 20 respectively can be obtained by plating the substrates 1a and 1b attached with fine metal particles (seed crystal). The protrusions 19 and 20 are formed at the surfaces of the junction layers 15a and 15b respectively in the same process as forming the junction layers 15a and 15b by plating. Alternatively, the junction layers 15a and 15b provided with the protrusions 19 and 20 respectively can be obtained by plating using a plating liquid in which the fine metal particles are suspended. In this case, the metal particles are attached to the substrate 1a and 1b, and the junction layers 15a and 15b are grown on the metal particles as the bases. This allows formation of the protrusions 19 and 20 at the surface of the junction layer 15 in the same process as forming the junction layers 15a and 15b respectively.

The shapes and dimensions of the second and third protrusions 19 and 20 can be controlled by the shape, dimension, plating time, and the like of the metal particles to be attached to the substrate 1. For example, the shapes of the second and third protrusions 19 and 20 are reflected on the shape of the used metal particles. Consequently, substantially cone shaped second and third protrusions 19 and 20 can be formed by using cone shaped metal particles. The dimension of the second and third protrusions 19 and 20 can be controlled by a plating time. The height h2 of the second and third protrusions 19 and 20 can be controlled by the height and the plating time of the metal particles to be used.

The junction layers 15a and 15b may have a metal layer made of, for example but without limitation, Ni or Au on the surfaces thereof in order to improve wettability with the second and the third solders 6c and 6d. In this case, each of the second and third protrusions 19 and 20 also comprise a metal layer of Ni or Au on the surface thereof.

### Example 1

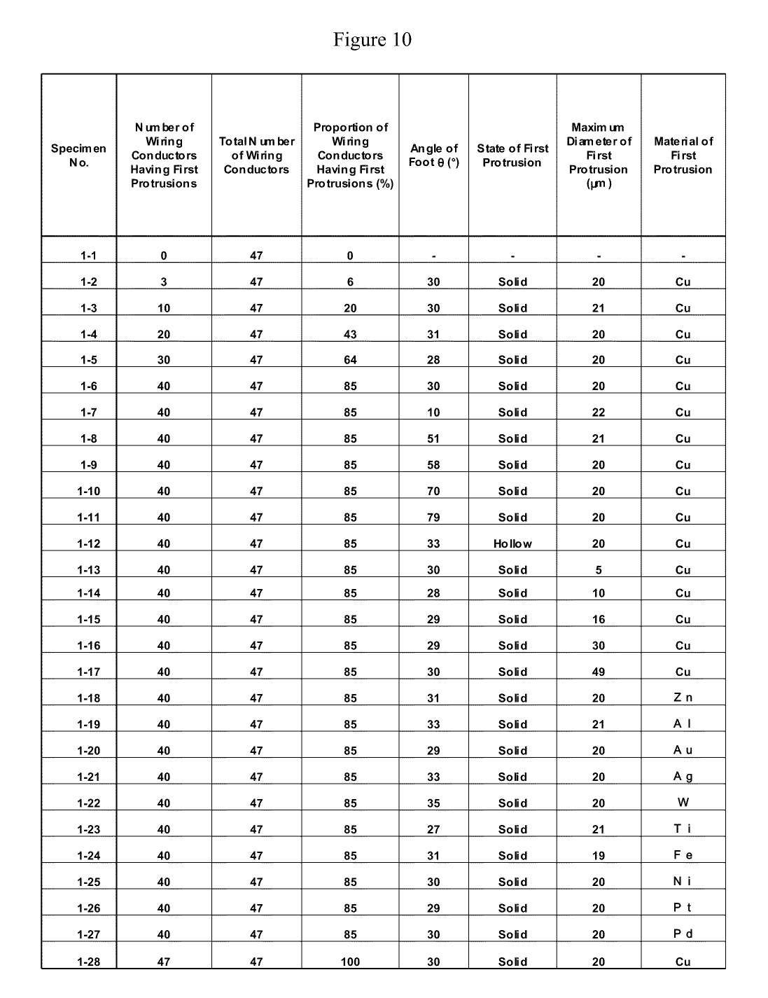

First, an n-type and p-type thermoelectric conversion element 2 made of a sintered body shown in FIG. 10 was prepared. The shape of the thermoelectric conversion element 2 was a quadrangular prism and a dimension thereof was about 0.6 mm in length, about 0.6 mm in width, and about 1 mm in height. Furthermore, as a substrate 1, an alumina substrate having a size of about 6 mm in length, about 8 mm in width, and about 0.2 mm in thickness was prepared.

Fine Cu particles each serving as a seed of a first protrusion 10 were attached to the substrate 1. A metal film was formed on the whole surface of the substrate 1 by the plating method, and the substrate 1 was etched to manufacture a conductor 3 in a predetermined shape with about 30 μm in thickness. In this case, the first protrusion 10, which is made of a material shown in FIG. 10 and has a circular shape when seen from the inner side, was manufactured at the surface of the conductor 3. The conductor 3 was formed of the same material as that of the first protrusion 10.

At the upper ends of thermoelectric conversion elements 2a and 2b having a low temperature, as shown in FIG. 5, four first protrusions 10 were formed in an area opposed to each of outer peripheral portions of end faces 22 and 24 of the thermoelectric conversion elements 2a and 2b, respectively. At the lower ends of the thermoelectric conversion elements 2a and 2b having a high temperature, as shown in FIG. 3, one first protrusion 10 was formed in an area opposed to each of central portions of end faces 21 and 23 of the thermoelectric conversion elements 2a and 2b, respectively.

Also, the proportion of the conductor 3 comprising the first protrusion 10 was obtained. In addition, confirmation was made on whether or not the first protrusion 10 was solid or hollow. These results are shown in FIG. 10. Further, an angle θ of foot 10a, a maximum diameter of the first protrusion 10, and materials for the first protrusion 10 are also shown in FIG. 10. As for the angle θ of the foot 10a and the maximum diameter of the first protrusion 10, angles θ of the foots 10a and the maximum diameters of the first protrusions 10 were obtained for twenty arbitrary first protrusions 10 (ten specimens for No. 1-2 in FIG. 10), and average values thereof were indicated in FIG. 10 as the angle θ of the foot 10a and the maximum diameter of the first protrusion 10, respectively. Furthermore, heights of the first protrusions 10 were obtained for the twenty arbitrary first protrusions 10 (ten specimens for No. 1-2 in FIG. 10), and calculated an average value thereof. The average value was as the height of the protrusion 10, which was at least about 1 μm. The height of the first protrusion 10 for the specimens Nos. 1-2 to 1-12, and 1-15 to 1-28 in FIG. 10 was not less than 5 μm.

The proportion of the conductors 3 comprised the first protrusions 10 controlled by the proportion of the fine Cu particles serving as the seeds attached to the substrate 1. The angle θ of the foot 10a was controlled by the shape of the Cu particle, and the maximum diameter and the height of the first protrusion 10 were controlled by dimension of the Cu particle, plating time, and the like. A hollow protrusion of each of the first protrusions 10 was manufactured by rapidly performing a heating process after plating.

A solder paste made of Au—Sn was printed on a conductor 3a on a first principle surface of first substrate 1a; and the thermoelectric conversion elements 2 were arranged thereon. Then, the thermoelectric conversion elements 2 were fixed to the first substrate 1a by heating from a second principal surface 12 on the opposite side of the first principal surface 11 arranged with the thermoelectric conversion elements 2. The number of the p-type thermoelectric conversion elements 2a was the same as that of the n-type thermoelectric conversion elements 2b. Similarly, an upper second substrate 1b and the thermoelectric conversion elements 2 were fixed together; and accordingly, a thermoelectric conversion module 9 was obtained. Further, external connection terminals 4 were formed on the substrates 1. The number of the conductors 3 was 24 on the first substrate 1a (including the external connection terminals 4), and 23 on the second substrate 1b, the total number thereof being 47.

A fourth solder 6b was supplied onto the external connection terminal 4 and was locally heated by soft beams or the like to connect a lead wire 5 to the external connection terminal 4.

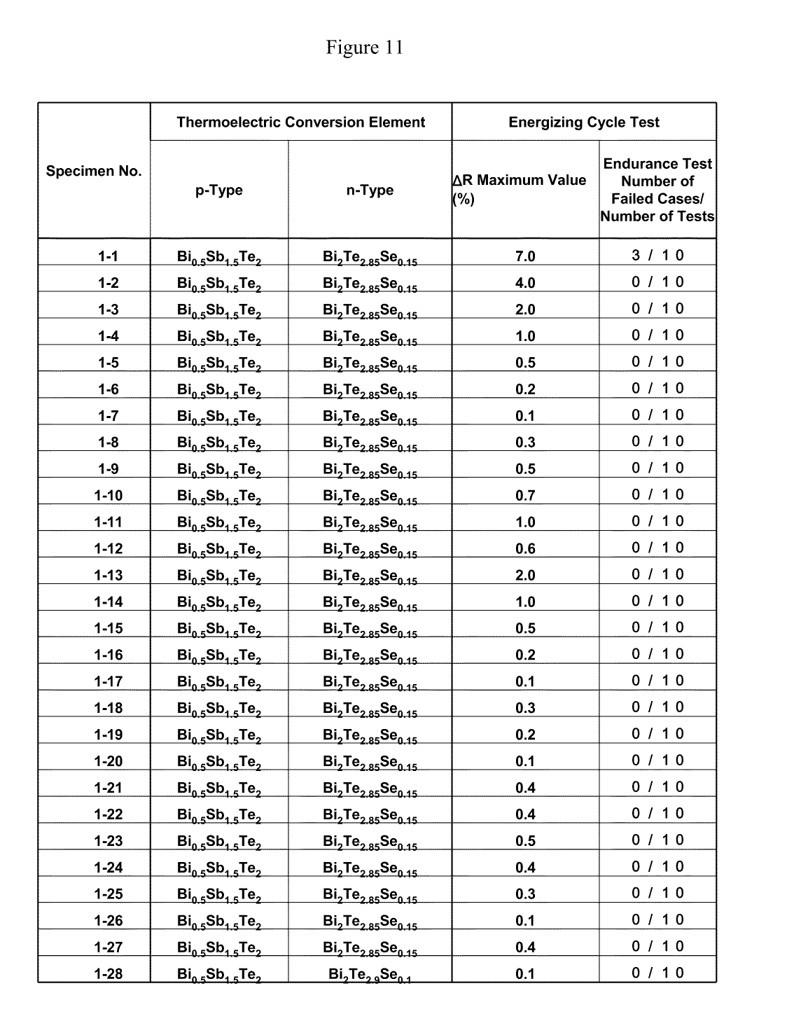

The thermoelectric conversion module 9 thus obtained was subjected to an energizing cycle test in which a cycle of inverting current polarities was repeated for 3000 times between a pair of lead wires 5 for every 15 seconds in oil at a temperature of about 30° C. Resistances before and after the test were measured using the electric conductivity measurement by AC 4 probes method. A resistance changing rate (ΔR) of not more than about 5% was regarded as passed while the resistance changing rate (ΔR) of more than about 5% was regarded as failed; and the numbers of failed cases for ten thermoelectric conversion modules are shown in FIG. 11.

According to FIGS. 10 and 11, the specimens Nos. 1-2 to 1-28 had a small ΔR which is not more than about 5%, and exhibited good repetition fatigue endurance. In these specimens, thermal stress between the thermoelectric conversion element and the first solder and between the conductor and the substrate was reduced, and a crack or peel-off was reduced. Among them, the specimens Nos. 1-4 to 1-12 and 1-14 to 1-28, in which the proportion of the conductors provided with protrusions was not less than about 30% and a maximum diameter of the protrusion was not less than about 10 μm, had a ΔR which is not more than about 1%, and exhibited an especially excellent repetition fatigue endurance.

On the other hand, the specimen No. 1-1 had failed cases in the endurance test, and was obviously inferior in repetition fatigue endurance. In this specimen, thermal stress between the thermoelectric conversion element and the element joining solder and between the conductor and the substrate was large, and a crack or peel-off was generated.

### Example 2

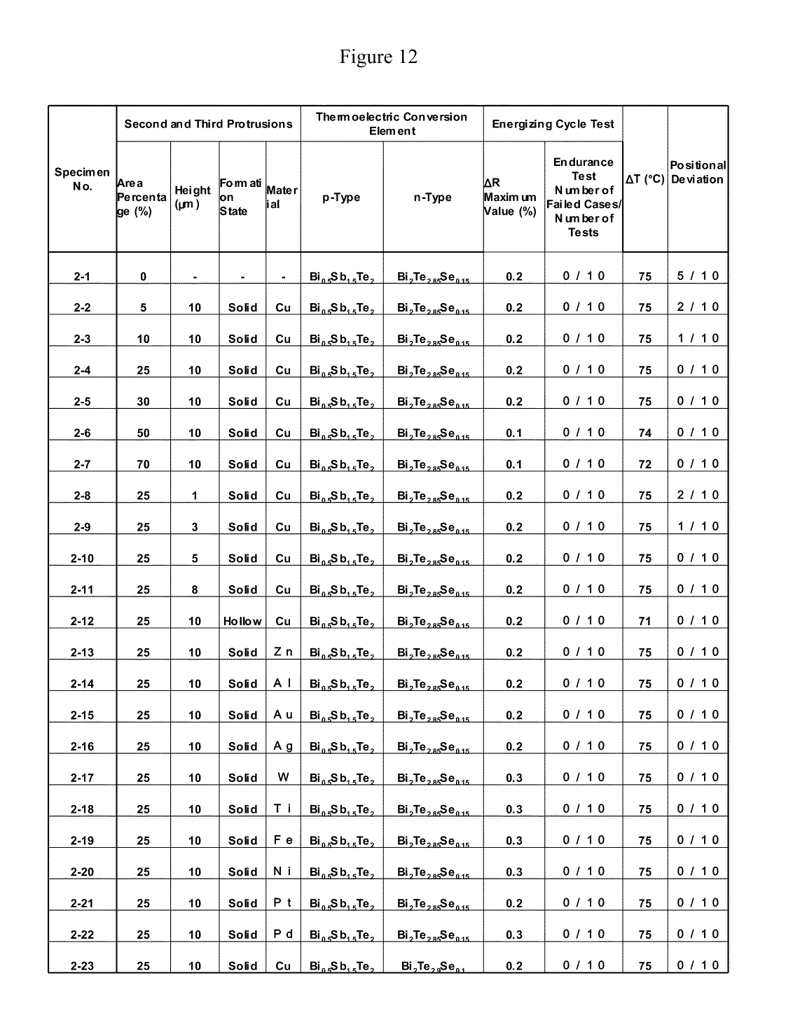

First, an n-type and a p-type thermoelectric conversion element 2 made of a sintered body shown in FIG. 12 was prepared. The shape of the thermoelectric conversion element 2 was a quadrangular prism and a dimension thereof was about 0.6 mm in length, about 0.6 mm in width, and about 1 mm in height. Furthermore, as substrates 1, two alumina substrates having a size of about 6 mm in length, about 8 mm in width, and about 0.2 mm in thickness were prepared.

Fine Cu particles serving as respective seeds of first, second, and third protrusions 10, 19, and 20 were attached to the first and second principal surfaces (both principal surfaces) of the two substrates 1. A metal film was formed on each of the whole surfaces of the both principal surfaces of the two substrates 1 by the plating method. This allows formation of junction layers 15 on ones of the principal surfaces of the two substrates 1 (a second principal surface 12 of a substrate 1a and a second principal surface 14 of a substrate 1b), and conductors 3 on the other principal surfaces of the two substrates 1 (a first principal surface 11 of the substrate 1a and a first principal surface 13 of the substrate 1b). Second and third protrusions 19 and 20, each of which is made of a material as shown in FIG. 12 and has a circular shape when seen from the inner side, were formed at surfaces of the junction layers 15 in the same process as the process of forming the junction layers 15. Furthermore, the conductors 3 formed on the first principal surface 11 of the first substrate 1a and the first principal surface 13 of the second substrate 1b had the first protrusions 10 as shown in FIGS. 2 to 5 at surfaces thereof. The conductors 3 were each etched to have a predetermined shape with about 30 μm in thickness. Further, external connection terminals 4 were formed on the substrates 1.

Area percentages of the second and third protrusions 19 and 20 occupied in the surfaces of junction layers 15a and 15b were calculated. The area percentages were obtained by tracing the second and third protrusions 19 and 20 in a 200 times SEM photograph (90 mm×120 mm) and by calculating using an image processing apparatus, results of which are indicated in FIG. 12. In addition, confirmation was made on whether or not the second and third protrusions 19 and 20 were solid or hollow; and results thereof are indicated in FIG. 12. Materials for the second and third protrusions 19 and 20 are also indicated in FIG. 12. According to the present example, the material for the junction layers 15 is the same as that for the second and third protrusions 19 and 20. For example, in the case where the material for the second and third protrusions 19 and 20 is Zn in FIG. 12, it means that the junction layers 15 are made of Zn. Further, heights of the second and third protrusions 19 and 20 in an area of the above SEM photograph (about 90 mm×120 mm) were obtained using a three dimension measuring instrument; and average values thereof are indicated in FIG. 12 as the height of the second and third protrusions 19 and 20.

The area percentages of the second and third protrusions 19 and 20 occupied in the surfaces of the junction layers 15 were controlled by the proportions of the fine Cu particles serving as the seeds attached to the substrates 1. Furthermore, the height of the second and third protrusions 19 and 20 was controlled by the sizes of the Cu particles. The hollow second and third protrusions 19 and 20 were manufactured by rapidly performing a heating process after plating.

The first protrusions 10 were formed on all the conductors 3, and an average angle θ of the foots 10a, an average maximum diameter of the first protrusions 10, and an average height of the first protrusions 10 were obtained as the angle θ of the foot 10a, the maximum diameter of the first protrusion 10, and the height of the first protrusion 10, respectively, as in the above example 1. As a result, the angle θ of the foot 10a was about 30 degrees, and the first protrusions 10 were solid and made of Cu. The maximum diameter of the protrusion 10 was about 20 μm, and the height of the first protrusion 10 was not less than about 5 μm.

Next, similar to the example 1, thermoelectric conversion elements 2 were joined to the substrates 1a and 1b by first solders 6a to manufacture a thermoelectric conversion module 9B. As in the example 1, a lead wire 5 was joined to the external connection terminal 4.

The same energizing cycle test as that of the example 1 was conducted for the thermoelectric conversion module 9B thus obtained. As in the example 1, a resistance changing rates (ΔR) and the numbers of failed cases in ten thermoelectric conversion modules are indicated in FIG. 12.

### Example 3

As in the example 2, a thermoelectric conversion module 9B was manufactured. Then, a second solder 6c and a third solder 6d were applied to the first and second junction layers 15a and 15b in the obtained thermoelectric conversion module 9B, respectively. A package 17 and a heat sink 18 were set to the second and third solders 6c and 6d and were joined to the first and second junction layers 15a and 15b by heating, respectively, and an optical transmission module 40 was manufactured.

First, a temperature difference (ΔT) was measured between the heat sink 18 and the package 17 upon supplying a current of 2A to the optical transmission module 40 thus obtained. Results thereof are shown in FIG. 12.

Further, each specimen was left in a high temperature tank at about 100° C. for about 1000 hours in a state where ten optical transmission modules 40 were set up (in a state where the substrate 1a and the substrate 1b are horizontally located as shown in FIG. 7 was rotated by about 90 degrees. In other words, in a state where the first substrate 1a and the second substrate 1b are vertically located). After about 1000 hours passed, positional deviation of the thermoelectric conversion module 9B with respect to the package 17 and positional deviation of the heat sink 18 with respect to the thermoelectric conversion module 9B were checked. Positional deviation was assumed in a case where at least one of the thermoelectric conversion module 9B and the heat sink 18 was positionally deviated, and the numbers of positional deviation is indicated in FIG. 12. In FIG. 12, for example, positional deviation of 5/10 indicates that five optical transmission modules 40 in ten optical transmission modules 40 had the positional deviations.

According to FIG. 12, the specimens Nos. 2-2 to 2-23 had a small ΔR which is not more than about 5%, and exhibited good repetition fatigue endurance. Furthermore, in these specimens, the number of positional deviations after the high temperature shelf test was small, namely, two optical transmission modules in ten optical transmission modules; and fixed force of each element was strong. Among these, in the specimens Nos. 2-4 to 2-7 and 2-10 to 2-23 having not less than about 25% of the area percentages of the second and third protrusions and not less than about 5 μm of the height of the second and third protrusions, no positional deviation was observed and fixed force of each element was especially excellent.

Although exemplary embodiments of the present disclosure have been described above with reference to the accompanying drawings, it is understood that the present disclosure is not limited to the above-described embodiments. Various alterations and modifications to the above embodiments are contemplated to be within the scope of the disclosure. It should be understood that those alterations and modifications are included in the technical scope of the present disclosure as defined by the appended claims.

While at least one exemplary embodiment has been presented in the foregoing detailed description, the present disclosure is not limited to the above-described embodiment or embodiments. Variations may be apparent to those skilled in the art. In carrying out the present disclosure, various modifications, combinations, sub-combinations and alterations may occur in regard to the elements of the above-described embodiment insofar as they are within the technical scope of the present disclosure or the equivalents thereof. The exemplary embodiment or exemplary embodiments are examples, and are not intended to limit the scope, applicability, or configuration of the disclosure in any way. Rather, the foregoing detailed description will provide those skilled in the art with a template for implementing the exemplary embodiment or exemplary embodiments. It should be understood that various changes can be made in the function and arrangement of elements without departing from the scope of the disclosure as set forth in the appended claims and the legal equivalents thereof. Furthermore, although embodiments of the present disclosure have been described with reference to the accompanying drawings, it is to be noted that changes and modifications may be apparent to those skilled in the art. Such changes and modifications are to be understood as being included within the scope of the present disclosure as defined by the claims.

Terms and phrases used in this document, and variations hereof, unless otherwise expressly stated, should be construed as open ended as opposed to limiting. As examples of the foregoing: the term “including” should be read as mean “including, without limitation” or the like; the term “example” is used to provide exemplary instances of the item in discussion, not an exhaustive or limiting list thereof; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent. The term “about” when referring to a numerical value or range is intended to encompass values resulting from experimental error that can occur when taking measurements.

1. A thermoelectric conversion module comprising:
a first substrate comprising a first principal surface;
a plurality of thermoelectric conversion elements on the first principal surface comprising first end faces and second end faces;
first conductors between the first principal surface and the first end faces operable to electrically connect the plurality of thermoelectric conversion elements to each other;
second conductors on the second end faces operable to electrically connect the plurality of thermoelectric conversion elements to each other; and
first solders located at least one of between the first conductors and the first end faces and between the second conductors and the second end faces, wherein
at least one of the first conductors and the second conductors comprise at least one first protrusion which protrudes toward the plurality of thermoelectric conversion elements and is coated by one of the first solders.

2. The thermoelectric conversion module according to claim 1, wherein the at least one first protrusion is located in at least one of:
an area of the first conductors opposed to the first end faces, and
an area of the second conductors opposed to the second end faces.

3. The thermoelectric conversion module according to claim 2, wherein:
each of the first conductors and each of the second conductors comprise the at least first protrusion, and
a position with respect to the first end faces of the at least one first protrusion in each of the first conductors is different from a position with respect to the second end faces of the at least one first protrusion in each of the second conductors.

4. The thermoelectric conversion module according to claim 3, wherein the at least one first protrusion of each of the first conductors is opposed to a central portion of the second end faces.

5. The thermoelectric conversion module according to claim 3, wherein the at least one first protrusion of each of the second conductors is opposed to an outer peripheral portion of the first end faces.

6. The thermoelectric conversion module according to claim 3, wherein:
the at least one first protrusion of each of the first conductors is opposed to a central portion of the second end faces, and
the at least one first protrusion of each of the second conductors is opposed to an outer peripheral portion of the first end faces.

7. The thermoelectric conversion module according to claim 1, wherein at least about 20% of the first conductors and the second conductors comprise the at least one first protrusion.

8. The thermoelectric conversion module according to claim 1, wherein a height of the at least one first protrusion is at least about 5 μm.

9. The thermoelectric conversion module according to claim 1, further comprising:
a second principal surface coupled to the first substrate;
a first junction layer on the second principal surface comprising a metal or an alloy; and
at least one second protrusion in the first junction layer protruding away from the plurality of thermoelectric conversion elements.

10. The thermoelectric conversion module according to claim 9, wherein an area percentage of the at least one second protrusion in a surface of the first junction layer is at least about 50%.

11. The thermoelectric conversion module according to claim 9, further comprising:
a second substrate comprising a first principal surface and a second principal surface, located on the second conductors with the first principal surface of the second substrate opposed to the second conductors; and
a second junction layer on the second principal surface of the second substrate comprising a metal or an alloy, wherein the second junction layer comprises at least one third protrusion which protrudes away from the plurality of thermoelectric conversion elements.

12. The thermoelectric conversion module according to claim 11, wherein an area percentage of the at least one second protrusion in a surface of the first junction layer is larger than an area percentage of the at least one third protrusion in a surface of the second junction layer.

13. An optical transmission module comprising:
a package;
a thermoelectric conversion module on the package comprising:
a first substrate comprising a second principal surface;
a first junction layer between the package and the second principle surface comprising a metal or an alloy; and
at least one protrusion in the first junction layer outwardly protruding; and
a solder located between the first junction layer and the package.

14. The optical transmission module according to claim 13, further comprising;
a laser apparatus on the thermoelectric conversion module; and
an additional solder between the thermoelectric conversion module and the laser apparatus; wherein
the thermoelectric conversion module comprises:
a second substrate comprising a first principal surface and a second principal surface, located with the first principal surface of the second substrate opposed to the first principal surface of the first substrate;
a plurality of thermoelectric conversion elements between the first substrate and the second substrate;
a second junction layer on the second principal surface of the second substrate comprising at least one of a metal and an alloy; and
at least one second protrusion in the second junction layer outwardly protruding; and wherein
the additional solder is between the second junction layer and the laser apparatus.

15. A thermoelectric conversion module comprising:
a first substrate comprising a first principal surface and a second principal surface;
a plurality of thermoelectric conversion elements on the first principal surface of the first substrate comprising first end faces and second end faces;
first conductors between the first principal surface and the first end faces operable to electrically connect the plurality of thermoelectric conversion elements to each other;
second conductors on the second faces operable to electrically connect the second end faces to each other;
first solders at least one of between the first conductors and the first end faces and between the second conductors and the second end faces; and
a first junction layer on the second principal surface comprising a metal or an alloy, wherein:
the first junction layer comprises at least one second protrusion extending away from the plurality of thermoelectric conversion elements.

16. The thermoelectric conversion module according to claim 15, further comprising:
a second substrate comprising a first principal surface and a second principal surface, and located on the second conductor with the first principal surface of the second surface opposed to the second conductor; and
a second junction layer on the second principal surface of the second substrate comprising the metal or the alloy, wherein:
the second junction layer comprises at least one third protrusion extending away from the plurality of thermoelectric conversion elements.

17. The thermoelectric conversion module according to claim 15, wherein an area percentage of the at least one second protrusion in a surface of the first junction layer is larger than an area percentage of the at least one third protrusions in a surface of the second junction layer.

18. A cooling device comprising:
the thermoelectric conversion module as set forth in claim 1 as a cooling unit.

19. A power generating device comprising:
the thermoelectric conversion module as set forth in claim 1 as a power generating unit.

20. A temperature adjusting device comprising:
the thermoelectric conversion module as set forth in claim 1 as a temperature adjusting unit.
